(19) United States
(12) Patent Application Publication
(10) Pub. No.: US 2019/0086809 A1
(43) Pub. Date: Mar. 21, 2019

(54) METHOD FOR FABRICATING SEMICONDUCTOR STRUCTURE INVOLVING CLEANING MASK MATERIAL

(71) Applicant: United Microelectronics Corp., Hsinchu (TW)

(72) Inventors: Tsung-Chieh Yang, Tainan City (TW); Chin-Che Hsu, Kaohsiung City (TW)

(73) Assignee: United Microelectronics Corp., Hsinchu (TW)

(21) Appl. No.: 15/711,864

(22) Filed: Sep. 21, 2017

(51) Int. Cl. G03F 7/42; H01L 21/306; H01L 21/02; H01L 21/768; H01L 21/3213

(52) U.S. Cl. CPC G03F 7/427; G03F 7/422; H01L 21/32133; H01L 21/0206; H01L 21/76808; H01L 21/30604

(57) ABSTRACT

A method for cleaning masking material is provided. A sacrificial layer is patterned to form a masking material over a semiconductor structure. The method includes plasma striping a top surface of the masking material, and cleaning the masking material by a hot ammonia solution.

### BACKGROUND

### 1. Field of the Invention

The present invention generally relates to semiconductor fabrication, and particularly to method for fabricating a semiconductor structure, involving cleaning mask material.

### 2. Description of Related Art

An integrated circuit is usually composed of a large number of semiconductor devices, which are fabricated by semiconductor fabrication technology. In addition, the interconnect structure is also involved in the integrated circuit for electric connection between the semiconductor devices. The semiconductor devices in an example are various designs of transistors, which can also be generally referred as a complementary metal-oxide-semiconductor (CMOS) circuit.

In fabricating the integrated circuit, the device structures are formed over a substrate step by step in various fabrication processes, which usually include the patterning process to form the structures. A different device structure usually involves a set of different process. Generally, a mask layer is used to mark over a portion of the substrate, which is not subjected to a current fabrication process. Taking the etching process as an example, a mask layer with the pattern is used to cover a portion over the substrate having the device structure, which is not to be etched by the current etching process.

The photoresist material is generally used as the mask material. However, the photoresist material is not the only choice. Some dielectric mask can also be taken for the masking use. When the photoresist material is used in an example, the photoresist material would be removed by cleaning process. However, the cleaning process may cause a damage to the exposed metal material. The dielectric mask is another choice, used for forming the mask layer. Even further, an organosiloxane polymer, such as DUO™ material, can be used as the mask layer. This DUO is a sacrificial material to cover the protected portion of the substrate. The DUO can be removed with less damage to the metal material. The DUO is also easily to enter an indent structure, such as a high aspect ratio indent structure, a trench, or a via. In other words, the DUO mask is also another choice to form the mask layer.

One issue needed to be concerned is how to clean the mask material from substrate with less damage to the exposed structure, such as the exposed metal layer.

### SUMMARY OF THE INVENTION

The invention provides a method for fabricating a semiconductor structure, involving cleaning mask material, in which the mask material can be cleaned with at least reduced damage to the exposed structure already formed but currently exposed by the mask material.

In an embodiment, the invention provides a method for cleaning masking material, wherein a sacrificial layer is patterned to form a masking material over a semiconductor structure. The method comprises plasma striping a top surface of the masking material, and cleaning the masking material by a hot ammonia solution.

In an embodiment, as to the method for cleaning masking material, the semiconductor structure comprises a trench, a via, or an indent.

In an embodiment, as to the method for cleaning masking material, the plasma striping includes a striping gas mixed of H₂ and N₂.

In an embodiment, as to the method for cleaning masking material, the top surface of the masking material is a skin layer, relatively harder than an inner portion of the masking material.

In an embodiment, as to the method for cleaning masking material, the hot ammonia solution is diluted by water.

In an embodiment, as to the method for cleaning masking material, the ammonia solution includes NH₃ and/or NH₄OH.

In an embodiment, as to the method for cleaning masking material, an operation temperature of the hot ammonia solution is in a range of 20° C. to 80° C.

In an embodiment, as to the method for cleaning masking material, an operation temperature of the hot ammonia solution is in a range of 50° C. to 70° C.

In an embodiment, as to the method for cleaning masking material, the semiconductor structure has a metal layer covered by the mask material.

In an embodiment, as to the method for cleaning masking material, the metal layer comprises TiN.

In an embodiment, the invention provides a method for fabricating a semiconductor device. The method comprises forming a semiconductor structure over a substrate. A sacrificial layer is formed over the semiconductor structure. The sacrificial layer is patterned to form a masking material on the semiconductor structure and expose a portion of the semiconductor structure. The masking material is removed by a process, comprising plasma striping a top surface of the masking material on the semiconductor structure, and cleaning the masking material by a hot ammonia solution.

In an embodiment, as to the for fabricating semiconductor device, the semiconductor structure comprises a trench, a via, or an indent.

In an embodiment, as to the for fabricating semiconductor device, the plasma striping includes a striping gas mixed of H₂ and N₂.

In an embodiment, as to the for fabricating semiconductor device, the top surface of the masking material is a skin layer, relatively harder than an inner portion of the masking material.

In an embodiment, as to the for fabricating semiconductor device, the hot ammonia solution is diluted by water.

In an embodiment, as to the for fabricating semiconductor device, the ammonia solution includes NH₃ and/or NH₄OH.

In an embodiment, as to the for fabricating semiconductor device, an operation temperature of the hot ammonia solution is in a range of 20° C. to 80° C.

In an embodiment, as to the for fabricating semiconductor device, an operation temperature of the hot ammonia solution is in a range of 50° C. to 70° C.

In an embodiment, as to the for fabricating semiconductor device, the semiconductor structure has a metal layer covered by the mask material.

In an embodiment, as to the for fabricating semiconductor device, the metal layer comprises TiN.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 to FIG. 9 are drawings of cross-section structures, schematically illustrating a flow for fabricating a semiconductor device, according to an embodiment of the invention.

FIG. 10 is a drawing, schematically illustrating the method for cleaning mask material, according to an embodiment of the invention.

FIG. 11 is a drawing, schematically illustrating the method for fabricating a semiconductor device, according to an embodiment of the invention.

### DESCRIPTION OF THE EMBODIMENTS

The invention is directed to method for fabricating a semiconductor structure, involving cleaning mask material.

The mask material such as the DUO (a trade mark) material can be used to cover the unwanted portion of a semiconductor structure, which is currently processed to form the semiconductor device, according to a design of an integrated circuit.

The DUO has properties to easily fill into an indent space, such as trench or via. The DUO material can serve like a dielectric mask material. This is an advantage when the device size is reduced, so to effectively cover the fine structure of the device under processing, like the indent structure. In other words, DUO material has good performance to fill the trench/via, and can be used as the dielectric material for subjecting to etching process. The DUO can protect the structure from etching process, particular to metal layer which has already been formed.

The DUO mask material is sacrificial material and is to be removed after the device is formed. The invention has looked into the issue to clean the mask material, such as DUO material. Taking the DUO as the mask material an example, it usually uses a cleaning recipe to remove the DUO material. The cleaning recipe as usually known is the CLK888 recipe. However, the CLK888 recipe is expensive and may also cause a damage on the exposed structure, particular to the mater structure not covered by the DUO mask.

The invention then proposes a cleaning procedure in fabricating the semiconductor device, so to replace the use of CLK888. The cleaning procedure in an embodiment comprises: plasma striping a top surface of the masking material; and cleaning the masking material by a hot ammonia solution. Remarkably, the masking material is not limited to the DUO material.

A number of embodiment are provided for describing the invention but not for limiting the invention.

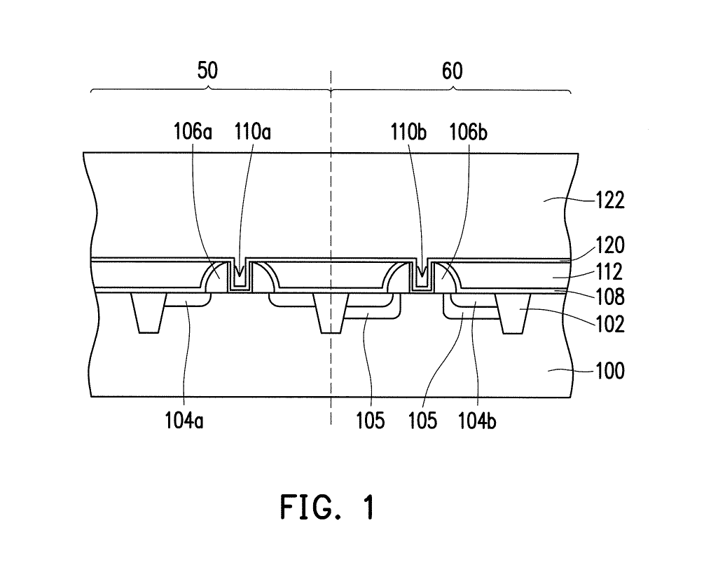

FIG. 1 to FIG. 9 are drawings of cross-section structures, schematically illustrating a flow for fabricating a semiconductor device, according to an embodiment of the invention.

Referring to FIG. 1, a semiconductor device is formed over a substrate 100 process by process. Here as an example, the semiconductor device can be a CMOS device, including a N-type metal-oxide-semiconductor (NMOS) transistor 50 and the P-type metal-oxide-semiconductor (PMOS) transistor 60 are formed on the same substrate 100.

It can be noted that the substrate 100 can be divided into a processing region 50 and the non-processing region 60. In an example, the processing region 50 may include the NMOS transistor to be forming and the non-processing region 60 may include the PMOS transistor 60 to be formed. The NMOS transistor in the processing region 50 and the PMOS transistor in the processing region 60 are different devices and subjected to different procedure. In addition, the NMOS transistor and the PMOS transistor as shown are also not the final transistor structures. The example is just to show the sacrificial layer 122, which is usually used to mask the device in the non-processing region 60 while the device in the processing region 50 is processed. The invention is not limited to the fabrication of NMOS transistor and the PMOS transistor.

Before the sacrificial layer 122, functioning as a sacrificial layer, is formed over the semiconductor substrate 100, the semiconductor substrate may include the substrate 100 and a semi-completion device having already been formed over the substrate 100. The semi-completion device as an example may include a NMOS device in the processing region 50 having the source/drain region 104a and a PMOS device in the non-processing region 60 having the source/drain region 104b with the epitaxial semiconductor layer 105, such as SiGe layer as formed by epitaxial growth. The isolation structure 102 are also formed in the substrate 100 to isolate the MOS devices.

In addition, depending on the various design of the transistor particular to the fin field effect transistor, the gate electrode is to be formed in different way. In the example, the gate electrode is to be formed later at the gate indent 110a in the processing region 50 and the gate indent 110b in the non-processing region 60. Remarkable, the NMOS transistor and the PMOS transistor in semi-completion structure are just the example, to which the invention is not limited.

The gate indents 110a, 110b may be originated form removing a dummy gate, on which the spacers 106a, 106b are formed on the dummy gate. Then, the dummy gate is then removed. The inter-layer dielectric layers 108, 112 are also involved to have the flat surface. The actual gate electrode is to be formed into the gate indents 110a, 110b in subsequent process. Again, as noted, the device structure in the processing region 50 and the device structure in the non-processing region 60 are not limited to the embodiments.

A metal layer 120, such as TiN layer, is then formed over the substrate 100. However, in the example, the metal layer 120 in the processing region 50 is to be removed while the metal layer 120 in the processing region 60 is reserved for the PMOS transistor. In this process, a sacrificial layer 122, is formed over substrate 100 at the processing region 50 and the non-processing region 60. The material of the sacrificial layer 122 can be dielectric material or the DUO material, or any proper material. The sacrificial layer 122 can efficiently fill into the gate indents 110a, 110b. The gate indents 110a, 110b can also be treated as a via or a trench with respect to the device structure different form MOS device as shown the embodiment.

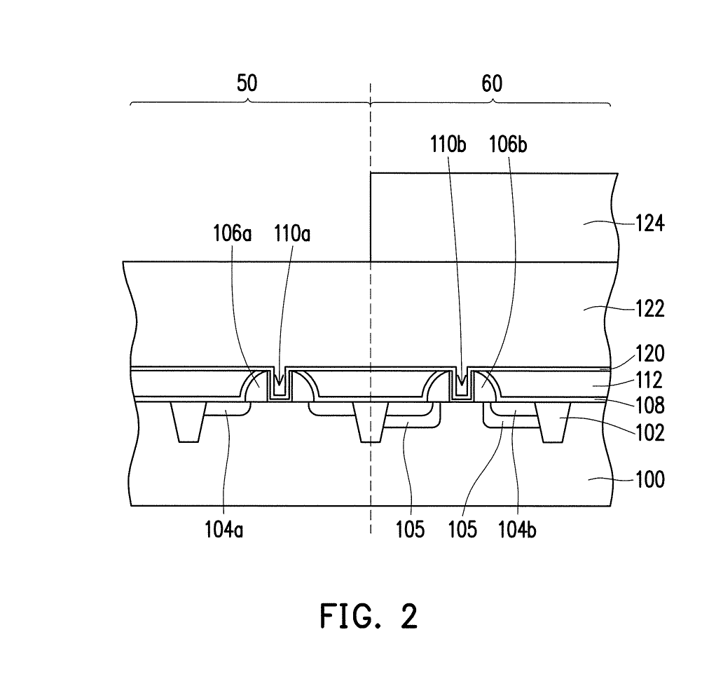

Referring to FIG. 2, a photoresist layer 124 is formed on the sacrificial layer 122 in the non-processing region 60. As noted, the sacrificial layer 122 in the fabrication procedure, the photoresist layer 124 is not directly used to as the mask layer, covering the device in the non-processing region 60.

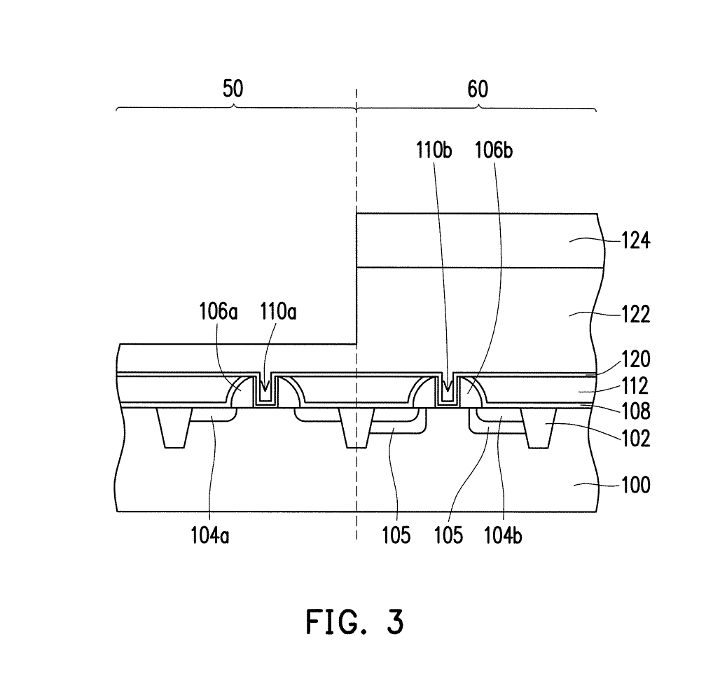

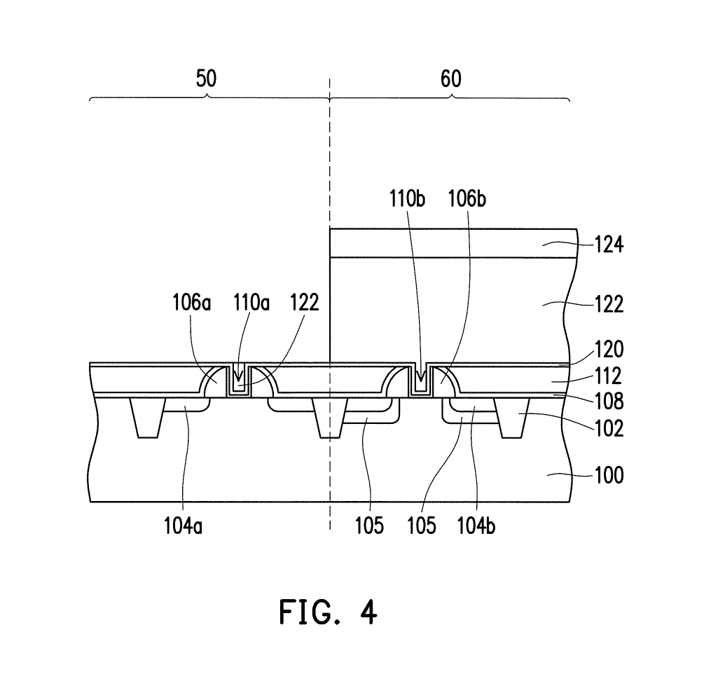

Referring to FIG. 3, the photoresist layer 124 and the sacrificial layer 122 can be etched ate the same etching process. Referring to FIG. 4, the sacrificial layer 122 in the processing region 50 is then removed to expose the metal layer 120. However, a residual portion of the sacrificial layer 122 still fills the gate indent 110a. At this stage, the photoresist layer 124 may be still not completely removed and still covers on the sacrificial layer 122 at the non-processing region 60 under the etching process.

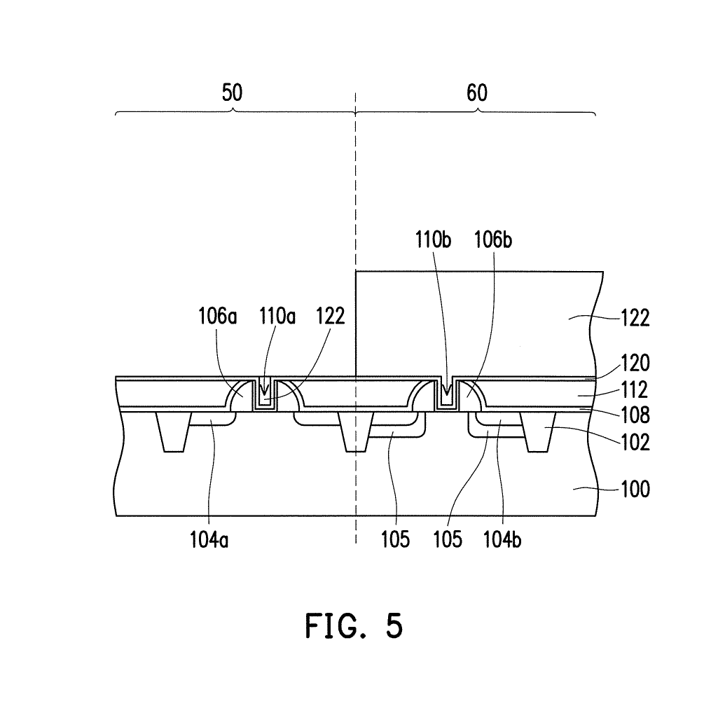

Referring to FIG. 5, the residue of the photoresist layer 124 is then stripped by a photoresist stripping process to actually remove the photoresist layer 124 on the sacrificial layer 122.

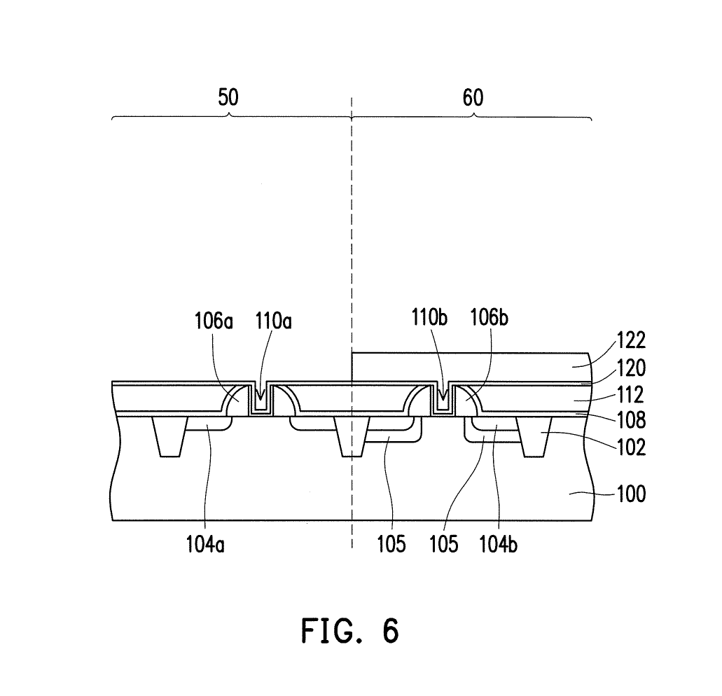

Referring to FIG. 6, the sacrificial layer 122 is further etched. Then, the residual portion of the sacrificial layer 122 in the gate indent 110a is removed to expose the metal layer 120 within the gate indent 110a. The sacrificial layer 122 now can function as a mask material or a mask layer to mask the non-processing region 60.

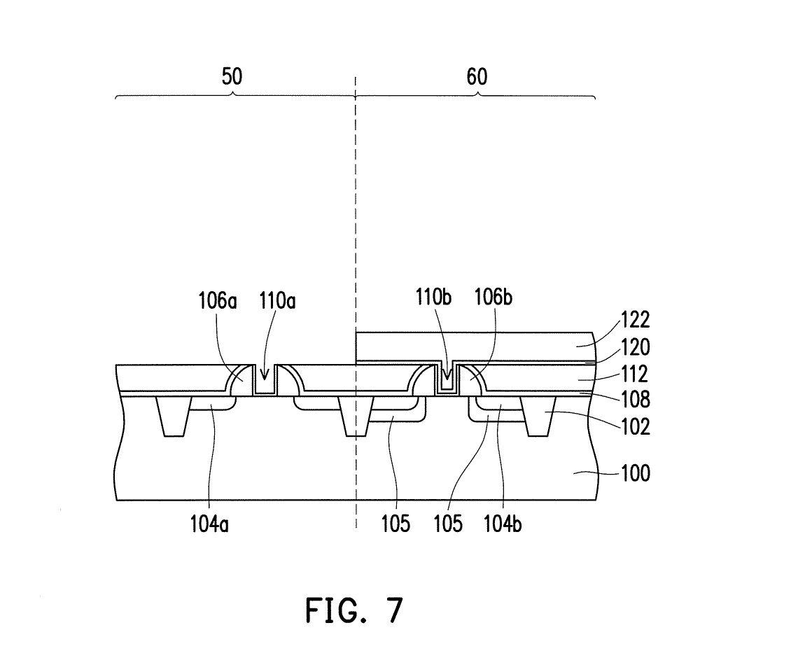

Referring to FIG. 7, using the patterned sacrificial layer 122 as the mask material in the non-processing region, the metal layer 120 in the processing region 50 is removed. A barrier layer in the gate indent 110a may still remain but the invention is not limited to. The portion of the metal layer 120 remains in the non-processing region 60 is intended for the device, such as the PMOS device.

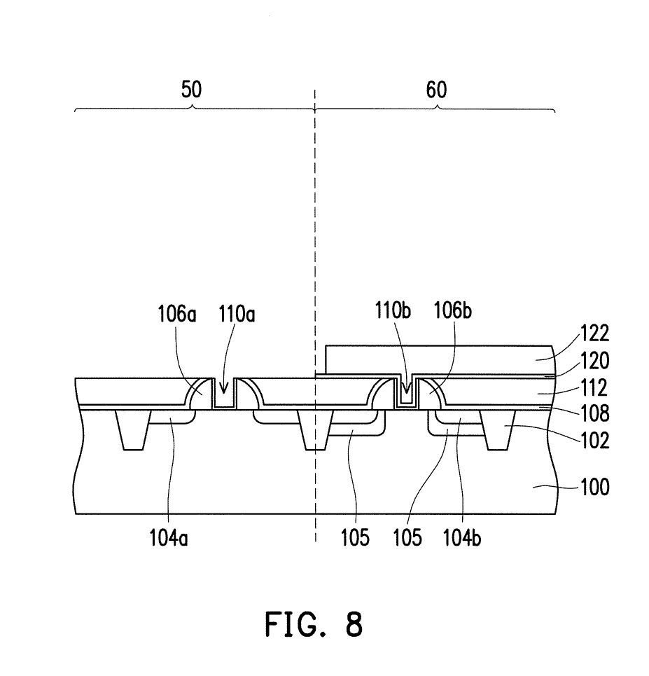

Referring to FIG. 8, the invention has proposed the method for cleaning the mask material of the sacrificial layer 122. The sacrificial layer 122 in an example is DUO material. Then, the invention does not used CLK888 recipe for cleaning DUO. The invention proposes a plasma stripping process to strip a top surface of the remaining sacrificial layer 122, which is a mask material. The plasma may use a mix of N₂ gas and H₂ gas so to remove the skin layer of the sacrificial layer 122. The top surface or the skin layer of the sacrificial layer 122 is harder than the inner portion of the sacrificial layer 122. So, this plasma stripping process can easily remove the hard portion.

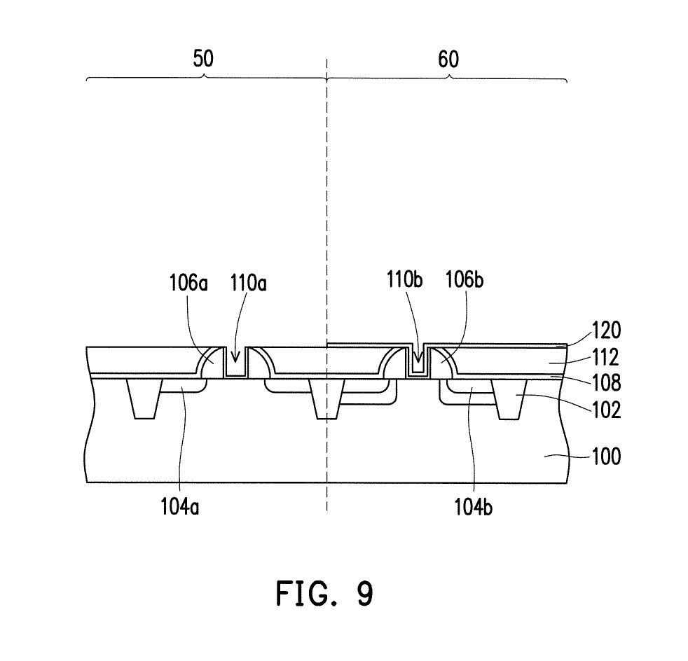

Referring to FIG. 9, since the hard portion of the sacrificial layer 122 has been stripped away, the remained sacrificial layer 122 is relatively soft and can be removed by a hot ammonia clean process by applying the solution of NH₃ and/or NH₄OH diluted by water. In an example, a ratio for ammonia to H₂O is about 1 to 5 at a temperature in a range of 20° C. to 80° C., such as 60° C. Then, the sacrificial layer 122 serving as the mask material is then cleaned away and the metal layer 120 in the non-processing region is exposed.

The invention cleans the mask material by plasm stripping the mask material, then subsequently cleaning the mask material by hot ammonia solution. The cleaning procedure needs no the CLK888 recipe. The invention allows the DUO to be used the mask material and to be cleaned by an easy process with less cost.

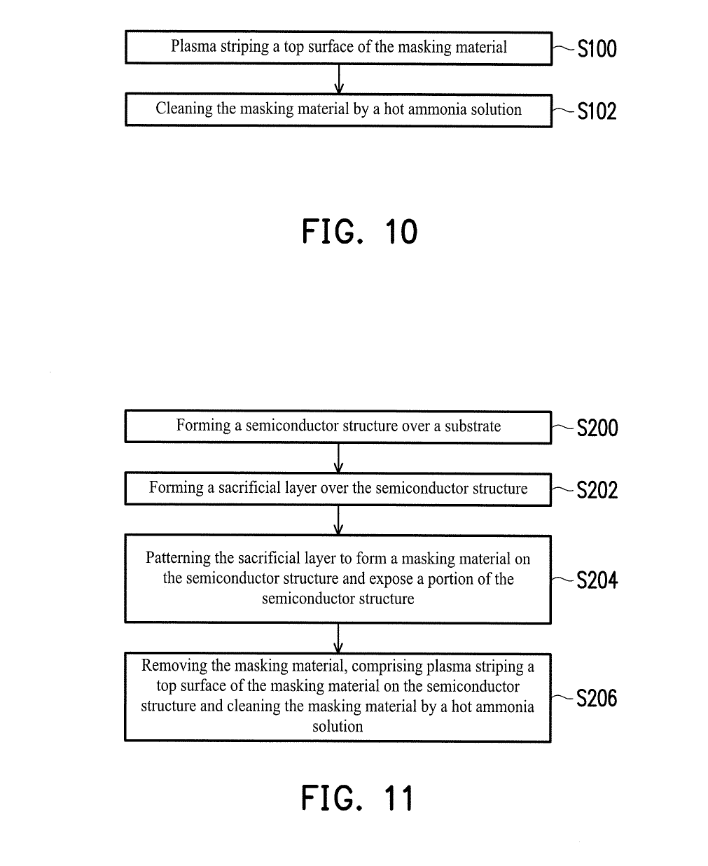

The invention can be generally described by the two steps. FIG. 10 is a drawing, schematically illustrating the method for cleaning mask material, according to an embodiment of the invention. Referring to FIG. 10, in step S100, a process of plasma striping a top surface of the masking material is performed. In step S102, a process of cleaning the masking material by a hot ammonia solution is performed.

Further to fabricating a semiconductor device, it also includes the process to remove the mask material. FIG. 11 is a drawing, schematically illustrating the method for fabricating a semiconductor device, according to an embodiment of the invention. In step S200, the method includes forming a semiconductor structure over a substrate. In step S202, the method includes forming a sacrificial layer over the semiconductor structure. In step S204, the method includes patterning the sacrificial layer to form a masking material on the semiconductor structure and expose a portion of the semiconductor structure. In step S206, the method includes removing the masking material, comprising plasma striping a top surface of the masking material on the semiconductor structure and cleaning the masking material by a hot ammonia solution.

The invention cleans the mask material by plasma striping a top surface of the masking material on the semiconductor structure and cleaning the masking material by a hot ammonia solution. The mask material can easily clean the mask material with less cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method for cleaning masking material, wherein a sacrificial layer is patterned to form a masking material over a semiconductor structure, the method comprising:
plasma striping a top surface of the masking material, wherein a lower portion of the masking layer under the top surface still remains; and
cleaning the masking material by an ammonia solution.

2. The method of claim 1, wherein the semiconductor structure comprises a trench, a via, or an indent.

3. The method of claim 1, wherein the plasma striping includes a striping gas mixed of H₂ and N₂.

4. The method of claim 1, wherein the top surface of the masking material is a skin layer, relatively harder than an inner portion of the masking material.

5. The method of claim 1, wherein the ammonia solution is diluted by water.

6. The method of claim 5, wherein the ammonia solution includes NH₃ and/or NH₄OH.

7. The method of claim 1, wherein an operation temperature of the ammonia solution is in a range of 20° C. to 80° C.

8. The method of claim 1, wherein an operation temperature of the ammonia solution is in a range of 50° C. to 70° C.

9. The method of claim 1, wherein the semiconductor structure has a metal layer covered by the mask material.

10. The method of claim 9, wherein the metal layer comprises TiN.

11. A method for fabricating semiconductor device, comprising:
forming a semiconductor structure over a substrate;
forming a sacrificial layer over the semiconductor structure;
patterning the sacrificial layer to form a masking material on the semiconductor structure and expose a portion of the semiconductor structure; and
removing the masking material, comprising:
plasma striping a top surface of the masking material on the semiconductor structure, wherein a lower portion of the masking layer under the top surface still remains; and
cleaning the masking material by an ammonia solution.

12. The method of claim 11, wherein the semiconductor structure comprises a trench, a via, or an indent.

13. The method of claim 11, wherein the plasma striping includes a striping gas mixed of H₂ and N₂.

14. The method of claim 11, wherein the top surface of the masking material is a skin layer, relatively harder than an inner portion of the masking material.

15. The method of claim 11, wherein the ammonia solution is diluted by water.

16. The method of claim 15, wherein the ammonia solution includes NH₃ and/or NH₄OH.

17. The method of claim 11, wherein an operation temperature of the ammonia solution is in a range of 20° C. to 80° C.

18. The method of claim 11, wherein an operation temperature of the ammonia solution is in a range of 50° C. to 70° C.

19. The method of claim 11, wherein the semiconductor structure has a metal layer covered by the mask material.

20. The method of claim 19, wherein the metal layer comprises TiN.
